(19) United States
(12) Patent Application Publication
(10) Pub. No.: US 2007/0099346 A1
(43) Pub. Date: May 3, 2007

(54) SURFACE TREATMENTS FOR UNDERFILL CONTROL

(75) Inventors: Mukta Farooq, Hopewell Junction, NY (US); Thomas Lombardi, Poughkeepsie, NY (US); Julie Nadeau Filtreau, Quebec (CA); Scott Bradley, Staatsburg, NY (US); Claude Blais, Quebec (CA); Richard F. Indyk, Wappingers Falls, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/163,832

(22) Filed: Nov. 1, 2005

(51) Int. Cl. H01L 21/00

(52) U.S. Cl. 438/108

(57) ABSTRACT

Methods to reduce or eliminate the bleed out of underfill material. Surface treatments to selective areas on a chip carrier substrate surface create a non-wettable surface or a reduced wettability surface in the areas where the underfill should not flow. The substrate surface is subjected to surface treatments such as media blasting or chemical exposure which will roughen the exposed surface.

### BACKGROUND OF THE INVENTION

The present invention is directed to interconnect structures for joining an integrated semiconductor device to a chip carrier substrate and particularly to the controlled application of encapsulant material to the semiconductor device connections to enhance the fatigue life of the semiconductor device solder connections.

Controlled Collapse Chip Connections (C4) or flip-chip technology has been successfully employed for interconnecting high I/O (input/output) count and area array solder bumps on silicon semiconductor devices or “chips” to ceramic chip carriers or substrates. Alumina and glass ceramic substrates are common examples of ceramic chip carriers. A problem with the chip join of silicon chips on ceramic chip carriers has been solder fatigue fails as a result of the coefficient of thermal expansion “CTE” mismatch between silicon (3 ppm/° C.) and alumina (6-8 ppm/° C.). The typical solution to this problem has been to encapsulate all the C4 joints in a polymeric encapsulant material, generally referred to as “underfill”.

Examples of common underfill materials are thermoset epoxy-based resins and epoxy/cyanate ester blends, usually filled with silica particles to lower the inherent resin CTE's (1,2). When highly filled with silica fillers (approximately 60 weight %), these materials generally have an elastic modulus in the 8-10 Giga Pascal range, which enables the material to remain stiff and relatively unmoving during thermal cycling. The underfill material thereby structurally couples the chip to the chip carrier and prevents or limits differential movement of the chip and chip carrier during thermal cycling. This mechanical coupling also reduces the fatigue damage on the solder, and extends the life of the solder join between chip and substrate.

Despite these benefits, the application of underfill material has created problems which can reduce overall module life or seriously degrade performance. One such problem occurs if neighboring components are contacted by the spreading or advancing underfill material during its application to the chip carrier, or subsequent processing. The underfill is typically dispensed by a syringe in close proximity to the C4 array or C4 cage of the chip. The module is usually held at 70 to 100° C. during underfill dispense. The dispensed material then starts to spread out and move. This phenomenon is referred to as “bleed out”. Bleed out is essentially a wetting phenomenon. Curing does not change the degree of spread since the spreading occurs primarily prior to curing. The bleedout speed is a maximum when the underfill viscosity is low at elevated temperatures, and bleedout comes to a stop as the underfill crosslinks at the curing temperature, typically in the range of 150 to 165° C.

If the areas surrounding the chip have other components attached, such as capacitors, or other passive devices, it may be preferable not to have the underfill touch those components. Underfill bleedout is a particular problem in the Bond, Assemble and Test (BAT) manufacturing sectors where chips and peripheral chip devices are attached to the substrate. An example of this situation is when Inter Digitated Capacitors (IDCs) are used in relatively close proximity to the chip. In such an instance, it is critical for the underfill to stay within the boundary or shadow of the chip. Underfill seepage into IDC joint areas, especially partial or incomplete encapsulation, can result in early failure of the IDC joints.

There is therefore a need to address this issue in BAT where underfill bleedout creates problems when neighboring components are reached by the advancing underfill front after the underfill is dispensed and starts to spread out and move. There is a need to prevent the underfill from reaching locations where it is not desired, such as the peripheral joints of the neighbor devices closest to the approaching front of underfill material. This is because the neighbor devices, such as IDC's, may be low-melt components. If they are encapsulated with underfill and are subjected to a subsequent second level reflow, melting of the solder in the components may occur. The volume expansion of the encapsulated solder during melting could cause problems, including extrusion of the solder material, resulting in shorting, etc.

There is therefore a need to better control the application and movement behavior of underfill material. This and other purposes of the present invention will become more apparent after referring to the following description considered in conjunction with the accompanying drawings.

### BRIEF SUMMARY OF THE INVENTION

The present invention discloses methods to reduce or eliminate the bleed out of underfill material. Surface treatments to selective areas on the chip carrier substrate surface create a non-wettable surface or a reduced wettability surface in the areas where the underfill should not flow. This provides control of the bleed out of the underfill such that the underfill does not bleed or “creep” into areas where it is not wanted, such as under peripheral chip components.

Areas of the substrate surface which need to exhibit wettability to the underfill are masked off. Theses areas include the chip C4 cage and capacitor sites. The masking creates exposed areas around the perimeter of the chip C4 cage where reduced wettability is desired. The masked substrate surface is subjected to surface treatments such as abrasive media blasting or chemical exposure which will roughen the exposed surface, or otherwise alter the ceramic surface energy.

The invention provides a method to control underfill dispense on a ceramic substrate comprising the steps of providing a ceramic substrate having a top surface to which semiconductor devices are attached, the top surface having a first area where underfill wetting is desired and a second area where underfill wetting is not desired; and applying a surface treatment to the second area to increase the surface roughness in the second area and thereby inhibit the wettability of underfill in the second area.

In one embodiment the surface treatment is abrasive media blasting. The media blasting may be a wet process or a dry process. The media blasting material preferably consists of glass beads, SiO₂, Al₂O₃, or silicon carbide.

In another embodiment the surface treatment comprises the application of chemicals which inhibit underfill wetting, for example, fluorocarbon polymers, such as polytetrafluoroethylene, PFTE (trade name Teflon). The chemicals are preferably applied with a brush, spraying or by a syringe dispense.

In another embodiment the surface treatment comprises the application of an etchant, preferably an hydroxide or hydrofluoric acid. The etchant is preferably applied with a brush, a syringe dispense, or a sponge which is immersed in the etchant and placed on the second area.

In another embodiment the method further comprises the step of masking the top surface prior to applying the surface treatment such that only the second area is exposed to the surface treatment. A preferred masking embodiment is placing the ceramic substrate in a fixture, the fixture having an opening to expose the second area. In another preferred embodiment the masking comprises applying a tape such as a rubber tape, to the first area.

### BRIEF DESCRIPTION OF THE DRAWINGS

The features of the invention believed to be novel and the elements characteristic of the invention are set forth with particularity in the appended claims. The Figures are for illustration purposes only and are not drawn to scale. The invention itself, however, both as to organization and method of operation, may best be understood by reference to the detailed description which follows taken in conjunction with the accompanying drawings in which:

FIG. 1 illustrates a conventional electronic module requiring underfill.

### DETAILED DESCRIPTION OF THE INVENTION

The purposes of the present invention have been achieved by providing methods of treating a chip carrier ceramic surface to change the wetting characteristics of the surface. The underfill will be less wettable to the treated surface, and this will reduce the bleed out of the underfill and prevent or mitigate the flow of the underfill encapsulation into undesired areas such as underneath the surface mount components. Preferred methods of treating the surface include media blasting or chemical exposure.

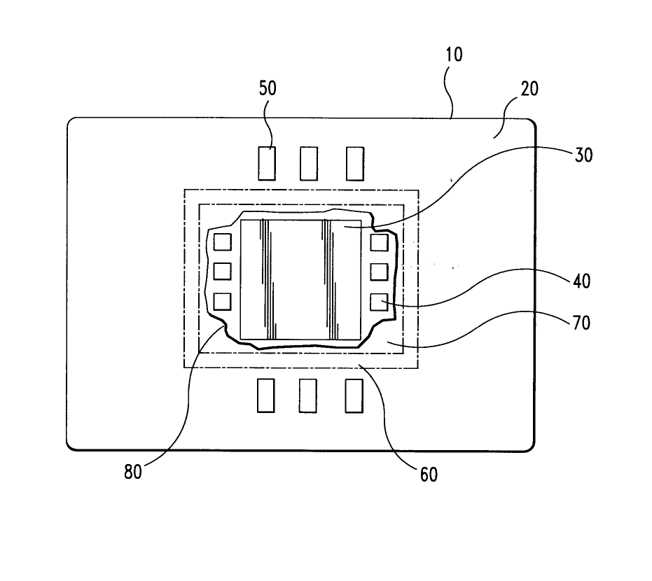

Referring to FIG. 1 there is shown a ceramic chip carrier substrate 10 having a top surface 20 to which a semiconductor chip 30, capacitors 40 and surface mount IDC components 50. There is an area 60 depicted where the surface is intentionally treated by media blasting, grit blasting, or chemical means, to prevent underfill bleed out. The surface treatment creates two regions on the top surface 20. One is the region 70 where the semiconductor chip and C4 capacitors are attached and underfill wetting is desired. A second is the region 60 where underfill wetting is not desired. This is the region separating the surface mount components 50 from the encapsulated semiconductor chip 30 and capacitors 40.

When underfill 80 is dispensed along the edge of the chip 30 or C4 capacitors 40, it flows under the chip body or C4 capacitor body, but it can also bleed out onto the ceramic surface. By roughening the surface as described in the present invention, the wetting characteristics are altered such that the underfill material will not flow as well on that roughened surface, so the present invention prevents/mitigates the possibility of getting undesirable underfill encapsulant material underneath the surface mount components 50. The present invention provides a non-wettable or a reduced wettability area 60 on the top surface the chip carrier 10, which surrounds the chip C4 cage and will prevent the underfill from flowing out.

It has been observed that the degree of bleedout is roughly inversely proportional to surface roughness. A lapped surface is roughest and has the least amount of bleedout. An as-sintered surface is least rough and has the most bleedout.

The present invention could be implemented at various stages in the chip carrier manufacturing process. For example, it could be implemented at the substrate level, incoming to bond and assembly, or it could be implemented as the first step in the bond and assembly area. The typical ceramic substrate process consists of punching holes or vias in green sheets. These green sheets are then screened with a conductive paste to fill the vias and create wiring patterns on the sheets. The sheets are then stacked and sintered to form the ceramic substrate. The substrate is then typically plated to form the desired metallurgy on the top and bottom surface connections.

In one embodiment of the present invention the surface treatment would be performed after plating. The substrate is secured in a fixture and the top surface is masked to only expose the area which will be surface treated. Exposed areas on the mask will be exposed to surface treatment and the unexposed or masked areas will be protected. The top surface, or TSM, is the surface of the substrate to which chips and devices are attached. Conversely, the bottom surface, or BSM, is the side of the substrate to which solder balls, columns, or other interconnects are placed for connection to a circuit board.

After the top surface of the substrate has been masked the exposed areas are surface treated. A preferred surface treatment is to media blast or grit blast the exposed surface areas on the top surface of the ceramic surrounding the C4 cage. This will create a band of media-blasted ceramic on the TSM of the chip carrier which surrounds the chip C4 cage. The roughened surface is less wettable to the underfill, and will act as a barrier to flow of the underfill, thus inhibiting the underfill from flowing outward from the C4 cage too far. The roughened surface is detectable by visual inspection and/or measurements of surface roughness such as surface profilometry.

Abrasive media blasting and grit blasting are well known processes. Media blasting is usually a wet process, and grit blasting could be wet or dry process. The materials used in either process could be the same, and can be chosen from a variety of materials, including glass beads, silica (SiO₂), alumina (Al₂O₃), and silicon carbide (SiC), as an example. The media blast parameters will depend on the media size, composition, hardness and substrate composition, and how those parameters will interact to achieve the desired roughness of the surface. An illustrative example, for a typical alumina ceramic substrate, would be a silica media, with a 40 to 80 psi nozzle pressure, with the nozzle about 6 inches from the substrate surface, and at a 45° incident angle to the surface. One skilled in the art would optimize the selection on media or grit blast parameters to achieve the desired surface roughness for a given substrate.

Another preferred surface treatment is chemical exposure of the unmasked area by a chemical which repels underfill wetting. This may be the application of the chemical onto the exposed surface with a brush, or other methods such as spraying or syringe dispense. Polytetrafluoroethylene (PFTE) is an example of a chemical that will repel underfill, and that could be applied in spray form, or applied with a brush or dispensed with a syringe.

Another preferred surface treatment is to expose the unmasked area to a ceramic etchant like a hydroxide or HF. This is followed by a rinse with water or other solvent. Hydrofluoric acid can be brush applied or syringe dispensed. Another embodiment is a window-frame shaped sponge or other material which acts as a carrier and transfer agent for the chemical, which is immersed in HF and then placed on the surface where the HF acts only on the desired area.

In another embodiment of the present invention the surface treatment would be performed during the bond and assembly process. A typical bond and assembly process includes application of flux to the chip site and C4 capacitor sites and then placement of chip and C4 capacitors. Then a high temperature furnace reflow is performed, typically at a maximum temperature of 360° C. This is followed by solvent flux cleaning, dispense of solder paste on surface mount component sites and placement of low temperature surface mount components such as IDC's. After a furnace reflow of approximately 220° C. maximum temperature the underfill encapsulation material is dispensed under the chip site and C4 capacitors. The underfill is typically cured at approximately 150-165° C. for 1-2 hours.

The present invention could be implemented at any point in the BAT process prior to the underfill dispense. It would preferably be implemented prior to chip or device attach to avoid any masking damage to the chip or devices.

Preferred masking techniques will depend on the type of surface treatment used. For media blasting the fixture used to hold the substrate itself could act as a mask. The substrate would be placed in a fixture that would have an opening to serve as the mask. Alternatively a fine stream abrasive media blast guided by Computer Numeric Control (CNC) tooling could be used without any masking on the substrate. Machine shop tools such as automatic milling machines and grinders are common examples of CNC based tools.

Another example of CNC tooling known in the art is an X-Y table which is driven to locations defined in a computer program. In this example the abrasive blast nozzle would be in a stationary location and the target substrate would be movable since it would be mounted on the X-Y table. In another embodiment the table and substrate could be held stationary and the blast nozzle location-programmable. In either embodiment the abrasive stream can also be turned on and off as a function of the CNC program.

In another embodiment a tape, such as a rubber tape, would be placed on the substrate to protect the surface areas which are not to be roughened. For chemical application such as brush apply, spraying or syringe dispense, no masking would be necessary. Masking could still be applied as a precaution against accidental application outside the desired areas.

It will be apparent to those skilled in the art having regard to this disclosure that other modifications of this invention beyond those embodiments specifically described here may be made without departing from the spirit of the invention. Accordingly, such modifications are considered within the scope of the invention as limited solely by the appended claims.

What is claimed is:

1. A method to control underfill dispense on a ceramic substrate comprising the steps of:
providing a ceramic substrate having a top surface to which semiconductor devices are attached, said top surface having a first area where underfill wetting is desired and a second area where underfill wetting is not desired;
and applying a surface treatment to said second area to increase the surface roughness in said second area and thereby inhibit the wettability of underfill in said second area.

2. The method of claim 1 wherein said surface treatment comprises media blasting.

3. The method of claim 2 wherein said media blasting is a wet process.

4. The method of claim 2 wherein said media blasting is a dry process.

5. The method of claim 2 wherein said media blasting material is selected from the group consisting of glass beads, SiO₂, Al₂O₃, and silicon carbide.

6. The method of claim 5 wherein said media blasting comprises a silica media, with a nozzle pressure of approximately 40 psi to approximately 80 psi and with the nozzle approximately 6 inches from said top surface, and at a 45° incident angle to said top surface.

7. The method of claim 1 wherein said surface treatment comprises the application of chemicals which inhibit underfill wetting.

8. The method of claim 7 wherein said chemicals are selected from the group consisting of fluorocarbon polymers.

9. The method of claim 7 wherein said chemicals are applied with a brush.

10. The method of claim 7 wherein said chemicals are applied by spraying.

11. The method of claim 7 wherein said chemicals are applied by a syringe dispense.

12. The method of claim 1 wherein said surface treatment comprises the application of an etchant.

13. The method of claim 12 where said etchant is selected from the group consisting of an hydroxide and hydrofluoric acid.

14. The method of claim 12 wherein said etchant is applied with a brush.

15. The method of claim 12 wherein said etchant is applied by a syringe dispense.

16. The method of claim 12 wherein said etchant is applied with a sponge which is immersed in said etchant and placed on said second area.

17. The method of claim 1 further comprising the step of masking said top surface prior to applying said surface treatment such that only said second area is exposed to said surface treatment.

18. The method of claim 17 wherein said masking further comprises placing said ceramic substrate in a fixture, said fixture having an opening to expose said second area.

19. The method of claim 17 wherein said masking further comprises applying a tape on said first area.

20. The method of claim 2 wherein said media blasting is a fine stream blast controlled by CNC tooling.
